(19) United States
(12) Patent Application Publication
(10) Pub. No.: US 2012/0249141 A1
(43) Pub. Date: Oct. 4, 2012

(54) METHOD FOR CORRECTING A DISTORTION IN A MAGNETIC RESONANCE RECORDING

(75) Inventors: Jan Ole Blumhagen, Erlangen (DE); Matthias Fenchel, Erlangen (DE); Ralf Ladebeck, Erlangen (DE)

(73) Assignee: SIEMENS AKTIENGESELLSCHAFT, Munich (DE)

(21) Appl. No.: 13/433,972

(22) Filed: Mar. 29, 2012

(30) Foreign Application Priority Data
Mar. 30, 2011 (DE) 102011006436.2

(51) Int. Cl. G01R 33/565; G01R 33/34

(52) U.S. Cl. 324/309; 324/322

(57) ABSTRACT

A method is disclosed for correcting a distortion in a magnetic resonance recording. A distortion indicates a mismatch between a distorted position of an image point in the magnetic resonance recording and an actual position of the image point. According to at least one embodiment of the method, a B₀ field deviation and a gradient field deviation are determined for at least one actual position in the magnetic resonance facility. Furthermore, a magnetic resonance recording of an examination object is captured and the actual position of an image point of the magnetic resonance recording is determined as a function of the distorted position of the image point in the magnetic resonance recording, the B₀ field deviation at the actual position and the gradient field deviation at the actual position.

### PRIORITY STATEMENT

The present application hereby claims priority under 35 U.S.C. §119 to German patent application number DE 10 2011 006 436.2 filed Mar. 30, 2011, the entire contents of which are hereby incorporated herein by reference.

### FIELD

At least one embodiment of the present invention generally relates to a method for correcting a distortion in a magnetic resonance recording and/or a magnetic resonance facility for this purpose.

### BACKGROUND

The measurable volume in a magnetic resonance facility is limited in all three spatial directions due to physical and technical conditions such as e.g. limited magnetic field homogeneity and non-linearity of the gradient fields. A recording volume or so-called field of view (FoV) is therefore limited to a volume in which the above cited physical conditions lie within predefined tolerance ranges, such that a true-to-original representation of the object to be examined is possible using normal measurement sequences. In particular, this limited field of view is considerably smaller in a transverse plane, i.e. in an x-direction and a y-direction perpendicular to a longitudinal axis of a tunnel of the magnetic resonance facility, than the volume that is delimited by the tunnel opening of the magnetic resonance facility. In the case of conventional magnetic resonance facilities, the tunnel has a diameter of 60 cm or 70 cm, for example, whereas the diameter of the field of view that is normally used (in which the above cited physical conditions are within the tolerance ranges) is approximately 50 cm or 60 cm.

Magnetic resonance recordings can therefore feature significant distortions depending on location, bandwidth and architecture of the magnetic and gradient field. A distortion indicates a mismatch between a position of an image point in the magnetic resonance recording and the actual position of the image point in the examination object. However, many applications require a spatially accurate representation, such as e.g. a specification of a human attenuation adjustment for positron emission tomography recordings, magnetic resonance-based interventions, or applications in which spatially accurate representation methods (e.g. computer tomography or positron emission tomography) are combined with magnetic resonance-based methods.

The problem that a spatially accurate representation of the measurement object is not possible in the margin region of the tunnel of the magnetic resonance facility, in particular, is normally solved in the case of purely magnetic-resonance recordings by arranging the region of the object to be examined not at the margin of the tunnel, but in the homogeneous low-distortion region or even if possible in the center of the tunnel, the so-called isocenter of the magnetic resonance facility. In the case of hybrid systems such as e.g. a hybrid system consisting of a magnetic resonance tomograph and a positron emission tomograph, a so-called MR-PET hybrid system, it is however crucially important for structures to be determined with the greatest spatial accuracy, even in the margin region.

In the case of an MR-PET hybrid system, the human attenuation adjustment is crucially important, for example. The human attenuation adjustment determines the intensity attenuation of the emitted photons (following an interaction of positrons and electrons) on their way through absorbent tissue to the detector, and corrects the received signal by precisely this attenuation. A magnetic resonance recording is captured for this purpose, representing the complete anatomy of the object to be examined in the direction of the high-energy photons emitted by the positron emission tomography. This means that the anatomy of the object to be examined must also be captured as accurately as possible in the margin region of the tunnel of the hybrid system. In the case of a patient to be examined, the structures found in this region are primarily e.g. the arms, which can be arranged in the margin region near to the tunnel inner wall of the hybrid system.

The prior art discloses various correction algorithms for correcting a distortion that occurs in particular outside the volume in which magnetic field inhomogeneity and non-linearity of the gradient field lie within specifications. For example, a gradient warp correction is proposed by S. Langlois et al. in “MRI Geometric Distortion: a simple approach to correcting the effects of non-linear gradient fields” (J Magn Reson Imaging 1999, 9(6): 821-31) and by S. J. Doran et al. in “A complete distortion correction for MR images: I. Gradient warp correction” (Phys Med Biol. 2005 Apr. 7; 50(7): 1343-61). Furthermore, a B0 field correction is proposed by S. A. Reinsberg et al. in “A complete distortion correction for MR images: II. Rectification of static-field inhomogeneities by similarity-based profile mapping” (Phys Med Biol. 2005 Jun. 7; 50(11):2651-61). However, the results of the proposed methods do not provide optimal results for warp correction in the margin region in particular, this being required in particular for determining an attenuation adjustment for a PET.

### SUMMARY

At least one embodiment present invention provides a spatially accurate representation of structures of an object to be examined in a region outside of the usual field of view, i.e. in particular in a margin region of the tunnel of the magnetic resonance facility.

In at least one embodiment, a method is disclosed for correcting a distortion in a magnetic resonance recording, a device is disclosed for correcting a distortion in a magnetic resonance recording, a magnetic resonance facility is disclosed, a computer program product is disclosed and an electronically readable data medium is disclosed. The dependent claims define preferred and advantageous embodiments of the present invention.

According to at least one embodiment of the present invention, a method is provided for correcting a distortion in a magnetic resonance recording. The magnetic resonance recording comprises image points of a sectional image recording of an examination object in a magnetic resonance facility. The sectional image recording can comprise a two-dimensional magnetic resonance recording or a three-dimensional magnetic resonance recording, for example. A distortion in the magnetic resonance recording is understood to signify a mismatch between a position of an image point in the magnetic resonance recording and an actual position of the image point in the examination object.

In other words, the distortion indicates a mismatch between a distorted position of an image point in the magnetic resonance recording and the actual position of the image point, at which the image point should actually be represented in the magnetic resonance recording. In this case, it is usually assumed that image points in the isocenter of the magnetic resonance facility exhibit no distortion or only very slight distortion, and can therefore be used as a reference for the positions and distortions of the other image points.

According to at least one embodiment of the method, a B0 field deviation and a gradient field deviation are determined for at least one actual position in the magnetic resonance facility. The B0 field deviation and the gradient field deviation can be determined by way of a preliminary measurement for any desired positions in the magnetic resonance facility, and stored in a memory of a processing unit of the magnetic resonance facility, for example. In this case, the B0 field and the gradient field can be measured once using a magnetic resonance sensor, for example.

According to at least one embodiment of the method, a magnetic resonance recording of the examination object is also captured in the magnetic resonance facility, and the actual position of an image point of the magnetic resonance recording is determined as a function of the distorted position of the image point in the magnetic resonance recording, the B0 field deviation at the actual position and the gradient field deviation at the actual position. On the basis of computable relationships between distorted and actual positions, the individual image points of the magnetic resonance recording can therefore be moved correspondingly in a post-correction.

According to an embodiment, for the purpose of determining the B0 field deviation and the gradient field deviation for the at least one actual position in the magnetic resonance facility, a B0 field strength and a gradient field strength are captured at the at least one actual position in the magnetic resonance facility and an ideal B0 field strength and an ideal gradient field strength are determined for the at least one actual position. The B0 field deviation is determined as a function of the captured B0 field strength and the ideal B0 field strength, and the gradient field deviation is determined as a function of the captured gradient field strength and the ideal gradient field strength. The B0 field strength and the gradient field strength for each actual position can be measured once in advance and normalized relative to the ideal field, for example, thereby allowing the determination of field coefficients that can be stored in a processing unit of the magnetic resonance facility. A single determination of the B0 field deviation and the gradient field deviation therefore provides all of the information that is required to allow distortions to be determined from a captured magnetic resonance recording of the examination object in the context of a post-correction.

According to a further embodiment, a corrected magnetic resonance recording is determined by virtue of an image point at an actual position in the corrected magnetic resonance recording being assigned an image point of the corresponding distorted position in the captured magnetic resonance recording. A distortion-corrected magnetic resonance recording can therefore be produced in a simple manner by means of processing individual image points.

According to a further embodiment, the method further provides for determining an arrangement of the examination object in the magnetic resonance facility on the basis of the corrected magnetic resonance recording, and determining an attenuation adjustment for a positron emission tomography recording as a function of the arrangement of the examination object in the magnetic resonance facility. Since the arrangement of the examination object in a positron emission tomography facility must be known as accurately as possible in order to determine the attenuation adjustment for a positron emission tomography recording, this information can be reliably determined by means of a magnetic resonance facility from the corrected magnetic resonance recording. In the case of a combined facility comprising a magnetic resonance tomograph and a positron emission tomograph, a so-called MR-PET hybrid facility, the attenuation adjustment thus determined can be used directly for a positron emission tomography recording.

According to a further embodiment, the magnetic resonance facility features a tunnel-shaped opening for accommodating the examination object. A margin of the field of view of the magnetic resonance facility comprises a circumferential region along an inner surface of the tunnel-shaped opening. Both the B0 field and the gradient fields usually fail to fully satisfy a homogeneity criterion in this circumferential region, and therefore it is not usually possible to provide a true-to-original spatially accurate representation of the examination object in this circumferential region.

In this embodiment, the actual position is situated in this circumferential region. The circumferential region can have a thickness of approximately 5 cm. The circumferential region therefore describes an annular region which is approximately 5 cm thick and is immediately adjacent to a surface of the tunnel-shaped opening of the magnetic resonance facility. In the case of a magnetic resonance facility having a tunnel diameter of e.g. 60 cm, homogeneity criteria for the B0 field and the gradient fields are only satisfied in a central region of approximately 50 cm, for example, such that the circumferential region extends beyond the region of homogeneity to the inner surface of the tunnel of the magnetic resonance facility. However, arms of a patient may be arranged in this region, for example, and have a significant influence on the attenuation adjustment for a positron emission tomography recording. It is therefore necessary for the position of the arms to be precisely determined. Due to the distortion in the circumferential region, it is however considerably more difficult to determine the position of the arms. By virtue of the above described method for correcting the distortion in the circumferential region, the position of the arms can be determined with greater accuracy and therefore a suitable attenuation adjustment can be determined, particularly if the magnetic resonance recording is captured in a transverse plane relative to the examination object.

According to at least one embodiment of the present invention, provision is further made for a device for correcting a distortion in a magnetic resonance recording. The magnetic resonance recording comprises image points of a sectional image recording of an examination object in a magnetic resonance facility. A distortion in the magnetic resonance recording signifies a mismatch between a distorted position of an image point in the magnetic resonance recording and an actual position of the image point in the examination object.

The device comprises an interface for receiving a magnetic resonance recording, a memory for storing a predetermined B0 field deviation and a predetermined gradient field deviation for at least one actual position in the magnetic resonance facility, and a processing unit. The processing unit can receive the magnetic resonance recording of the examination object from the magnetic resonance facility via the interface, and determine the actual position of an image point of the magnetic resonance recording as a function of the distorted position of the image point in the magnetic resonance recording, the B0 field deviation at the actual position and the gradient field deviation at the actual position. It is therefore possible to effect a post-correction of a captured magnetic resonance recording in order to obtain spatially accurate information relating to the arrangement of the examination object in the magnetic resonance facility. This spatially accurate information can be used to determine an attenuation adjustment for a subsequent positron emission tomography recording, for example.

Furthermore, the device can be configured to perform the method described above or one of its embodiments and can therefore feature the advantages described above.

At least one embodiment of the present invention also provides a magnetic resonance facility comprising a control unit for activating a tomograph, which has a magnet that is used to generate a B0 field in a field of view of the magnetic resonance facility, and for receiving signals that have been picked up by the tomograph, and an evaluation device for evaluating said signals and producing magnetic resonance recordings. The magnetic resonance facility additionally comprises the device described above and therefore also features the advantages described above. Furthermore, the magnetic resonance facility can comprise a positron emission tomograph. Such a facility is also known as an MR-PET hybrid facility. Since the magnetic resonance facility allows a spatially accurate determination of the examination object to be performed in the magnetic resonance facility, it is also possible to perform a precise attenuation adjustment for a positron emission tomography recording.

At least one embodiment of the present invention also provides a computer program product, in particular a computer program or software, which can be loaded into a memory of a programmable processing unit of a device for correcting a distortion. Using this computer program product, all or various of the described embodiments of the inventive method can be executed when the computer program product runs in the processing unit. In this case, the computer program product might require programming resources such as libraries or help functions, for example, in order to realize the corresponding embodiments of the method. In other words, the claim relating to the computer program product is intended to include in the scope of protection in particular a computer program or software by means of which one of the above described embodiments of the inventive method can be executed and/or which executes said embodiment. In this case, the software can be a source code (e.g. C++) which remains to be compiled or translated and linked or which merely needs to be interpreted, or an executable software code which merely needs to be loaded into the relevant processing unit for execution.

Lastly, at least one embodiment of the present invention provides an electronically readable data medium, e.g. a DVD, a magnetic tape or a USB stick, on which is stored electronically readable control information, in particular software, as described above. When this control information and/or software is read from the data medium and stored in the processing unit, all of the inventive embodiments of the described method can be performed.

### BRIEF DESCRIPTION OF THE DRAWINGS

In the following detailed description, example embodiments not to be understood in a limiting sense together with their features and further advantages will be described with reference to the accompanying drawings in which:

FIG. 1 schematically shows a magnetic resonance facility according to an embodiment of the present invention,

FIG. 2 shows a flow diagram of a method comprising steps for correcting a distortion in a magnetic resonance recording,

FIG. 3 shows a magnetic resonance recording which includes a distorted structure of an examination object, and

FIG. 4 shows a magnetic resonance recording that was produced by correcting the magnetic resonance recording from FIG. 3.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Before discussing example embodiments in more detail, it is noted that some example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed below, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks will be stored in a machine or computer readable medium such as a storage medium or non-transitory computer readable medium. A processor(s) will perform the necessary tasks.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the following description, illustrative embodiments may be described with reference to acts and symbolic representations of operations (e.g., in the form of flowcharts) that may be implemented as program modules or functional processes include routines, programs, objects, components, data structures, etc., that perform particular tasks or implement particular abstract data types and may be implemented using existing hardware at existing network elements. Such existing hardware may include one or more Central Processing Units (CPUs), digital signal processors (DSPs), application-specific-integrated-circuits, field programmable gate arrays (FPGAs) computers or the like.

Note also that the software implemented aspects of the example embodiments may be typically encoded on some form of program storage medium or implemented over some type of transmission medium. The program storage medium (e.g., non-transitory storage medium) may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The example embodiments not limited by these aspects of any given implementation.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

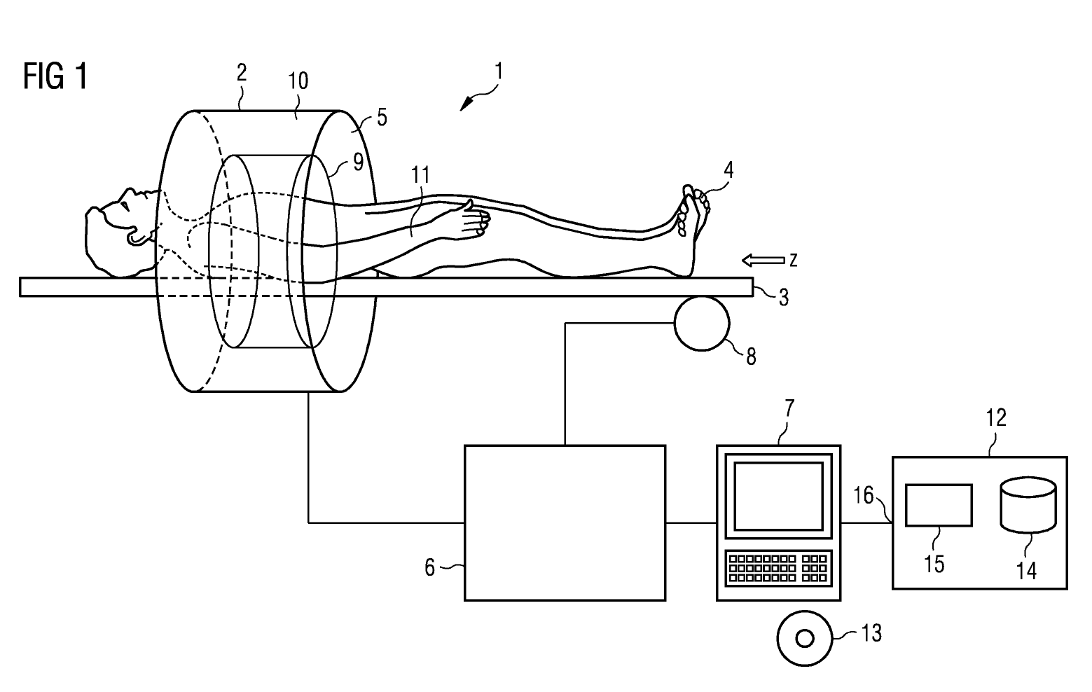

FIG. 1 shows a magnetic resonance facility 1. The magnetic resonance facility 1 comprises the actual tomograph 2, an examination table 3 for a patient 4 who is situated in an opening 5 of the tomograph 2, a control unit 6, an evaluation device 7, a drive unit 8 for the examination table 3 and a device 12 for correcting a distortion in a magnetic resonance recording. The control unit 6 activates the tomograph 2 and receives signals from the tomograph 2 that have been picked up by the tomograph 2. Furthermore, the control device 6 activates the drive unit 8 in order to move the examination table 3 and the patient 4 in a direction Z through the opening 5 of the tomograph 2. The evaluation device 7 evaluates the signals that have been picked up by the tomograph 2, in order thereby to create a magnetic resonance image (MR image) or magnetic resonance recording. The evaluation device 7 is e.g. a computer system comprising a display screen, a keyboard, a pointing device such as e.g. a mouse, and a data medium 13 on which is stored electronically readable control information that is so configured as to perform the method for correcting a distortion in a magnetic resonance recording as described below when said data medium 13 is used in the evaluation device 7 and the device 12.

The device 12 comprises a processing unit 15, a memory 14 and an interface 16 for linking the device 12 to the evaluation device 7. The data medium 13 can comprise e.g. program segements/modules for the evaluation device 7 and the device 12. Moreover, the control unit 6, the evaluation device 7 and/or the device 12 can also be designed in the form of a shared device, which uses a shared processing unit and a shared memory.

The magnetic resonance facility 1 is able to produce a magnetic resonance tomography recording within the volume that is delimited by the opening 5 in the interior of the tomograph 2. Due to physical/technical shortcomings, e.g. a magnetic field inhomogeneity of a B0 field extending in a Z direction and a non-linearity of gradient fields in the tomograph 2, the volume of the magnetic resonance facility 1 that can actually be used for magnetic resonance recordings is limited e.g. to the volume 9 which extends spherically or cylindrically in the interior of the opening 5. As shown in FIG. 1, in particular a circumferential region 10 which is situated between the usable volume 9 and an inner wall or inner surface of the tomograph 2 is unusable or can only be used to a limited extent due to the physical/technical shortcomings described above.

If the magnetic resonance facility 1 is used to determine the position and anatomy of the patient 4, e.g. for use in combination with a positron emission tomograph (not shown), it is nonetheless necessary to determine the complete anatomy of the patient 4 in the beam direction of the positron emission tomograph, i.e. the anatomy of the patient 4 is also required in the circumferential region 10 in particular, in order to capture e.g. the arms 11 of the patient 4. On the basis of the captured anatomy of the patient 4, it is then possible to determine a human attenuation adjustment, this being crucially important for the evaluation of the positron emission tomography recording.

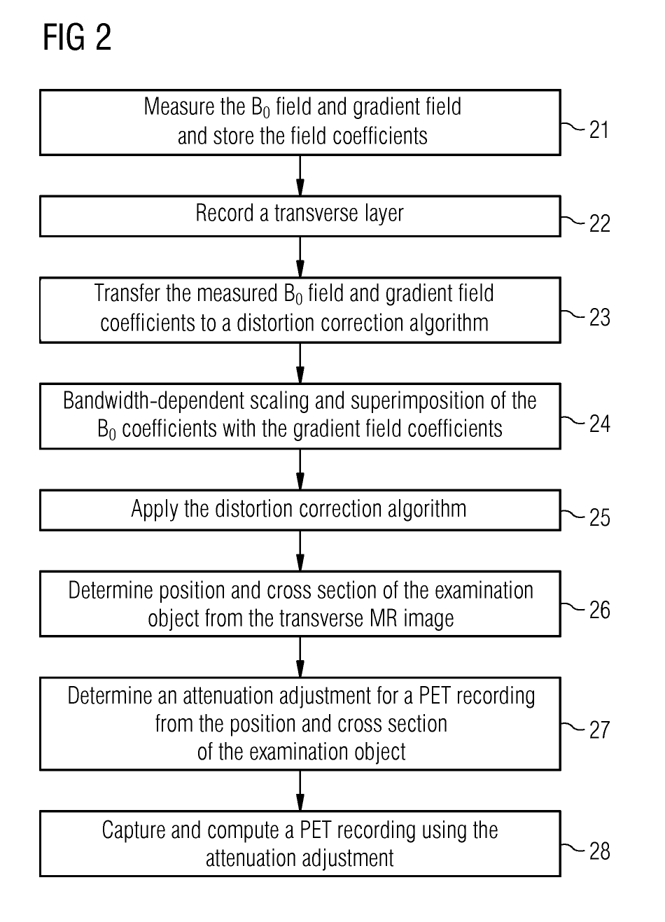

In the case of magnetic resonance recordings, so-called distortions occur in the circumferential region 10 as a result of the above described physical/technical shortcomings. A distortion means that an image point in the magnetic resonance recording does not appear at the position at which it actually should appear according to the examination object that has been recorded. Instead of appearing at the actual position, the image point appears at a distorted position. A method comprising the steps for correcting such a distortion in a magnetic resonance recording is described below with reference to FIG. 2.

In the step 21, the B0 field is measured and normalized relative to an ideal field, thereby determining B0 field coefficients and gradient field coefficients. The B0 field coefficients therefore signify a field deviation dB0 of the B0 field relative to the nominal value of the ideal field, and the gradient field coefficients signify the field deviations dBgx, dBgy and dBgz relative to the respective nominal value of the ideal gradient fields Gx, Gy, and Gz. The field coefficients and/or field deviations are stored in the memory 14 of the device 12 for predetermined points or all points of the volume 9 and in particular of the circumferential region 10.

In the step 22, a magnetic resonance recording is made of a transverse layer of the examination object 4, for example. The magnetic resonance recording produced in this way is transferred via the interface 16 to the processing unit 15 of the device 12 for post-correction of the distortion. The measured B0 field coefficients and gradient field coefficients are supplied to the processing unit 15 from the memory 14. In the processing unit 15, bandwidth-dependent scaling and superimposition of the B0 field coefficients with the gradient field coefficients is performed (step 24), and a distortion correction is performed (step 25) for each image point in accordance with the following equations:

$${z}_{1} = z + \frac{{dB}_{gz} ( x , y , z )}{{G}_{z}} + \{ \begin{matrix}\frac{{dB}_{gz} ( x , y , z )}{{G}_{z}} & if {G}_{z} is not a phase encoding gradient \\ 0 & if {G}_{z} is a phase encoding gradient\end{matrix} \\ {x}_{1} = x + \frac{{dB}_{gx} ( x , y , z )}{{G}_{x}} + \{ \begin{matrix}\frac{{dB}_{0} ( x , y , z )}{{G}_{x}} & if {G}_{x} is not a phase encoding gradient \\ 0 & if {G}_{x} is a phase encoding gradient\end{matrix} \\ {y}_{1} = y + \frac{{dB}_{gy} ( x , y , z )}{{G}_{y}} + \{ \begin{matrix}\frac{{dB}_{0} ( x , y , z )}{{G}_{y}} & if {G}_{y} is not a phase encoding gradient \\ 0 & if {G}_{y} is a phase encoding gradient .\end{matrix}$$

In the above equations, x, y and z designate coordinates of the actual position of an image point and x1, y1 and z1 designate coordinates of the distorted position of the image point. Furthermore, dB0(x, y, z) designates the B0 field coefficients at the actual position x, y, z and dBgx, dBgy and dBgz designate the gradient field coefficients of the gradients in an x-direction, y-direction and z-direction respectively at the actual position x, y, z. Gx, Gy and Gz designate the gradient field strengths of the gradient fields in an x-direction, y-direction and z-direction respectively. As shown in the equations above, the final summand is zero if the gradient in the corresponding direction is a phase encoding gradient. Otherwise, i.e. if the gradient in the corresponding direction is a layer selection gradient or a frequency encoding gradient, the final summand consists of the B0 field coefficient, normalized relative to the corresponding gradient field strength. By virtue of applying this warp correction algorithm in the processing unit 15, each image point of the distorted magnetic resonance recording can be moved accordingly and a corrected magnetic resonance recording is therefore produced. This can be transferred to the evaluation device 7, e.g. via the interface 16, for display or further processing there.

In the step 26, for example, the corrected magnetic resonance recording can be used as a basis for determining position and cross-section of the examination object or patient 4 in a transverse magnetic resonance recording in particular. As a result of the previously performed distortion correction, position and cross-section of the examination object can be determined with significantly greater accuracy. Using the position and the cross-section that have been determined thus for the patient 4, it is therefore now possible to determine an attenuation adjustment for a positron emission tomography recording (PET recording) in the step 27. In the step 28, data for creating a PET recording is captured, and a PET recording of the examination object or patient 4 is computed using the previously determined attenuation adjustment.

Since the B0 field coefficients and gradient field coefficients were also determined for the circumferential region 10, the warp correction can also be reliably performed in the circumferential region 10. It is therefore also possible reliably to detect regions of the patient 4 (e.g. the arms 11) that are arranged in the circumferential region 10 during the examination, and reliably to determine their position and cross-section, in order that they can be taken into consideration when determining the attenuation adjustment for the PET recording, for example. The usable field of view (FoV) is therefore extended to the whole inner diameter of the tunnel-shaped opening of the tomograph 2. This can be used not only to determine the human attenuation adjustment in the case of PET recordings, but also to provide support in the context of image-based radiotherapy planning and biopsy, for example.

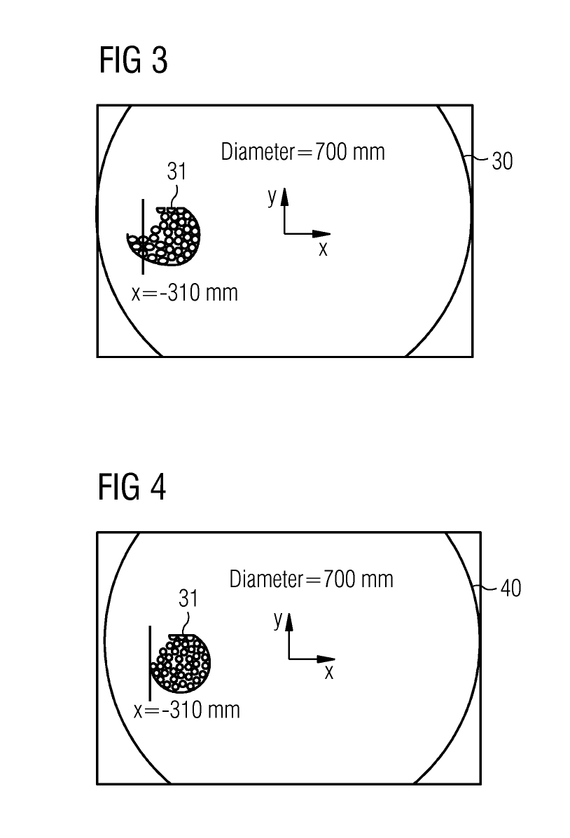

FIG. 3 shows a magnetic resonance recording 30 of a transverse layer of a structure phantom 31 which is arranged in a tomograph having a 700 mm diameter, where x=−310 mm. The coordinate source, i.e. x=0 and y=0, is located at the center of the tomograph 2. The transverse layer was captured at z=0, i.e. also in the center of the tomograph 2 in a longitudinal direction. FIG. 3 shows the magnetic resonance recording 30 without post-correction. The distortion of the structure phantom 31 is clearly recognizable. Many image points of the structure phantom 31 appear in the region x=−310 to −350 mm in the magnetic resonance recording as per FIG. 3, even though the structure phantom does not actually extend beyond x=−310 mm.

FIG. 4 shows a warp-corrected magnetic resonance recording 40 of the structure phantom 31, which was produced on the basis of the magnetic resonance recording 30 as per FIG. 3. The arrangement and the cross-section of the structure phantom 31 in FIG. 4 are significantly more true-to-original than in FIG. 3.

In order to achieve successful post-correction, excessive distortion must be avoided. If distortion is too pronounced, a plurality of image points in the uncorrected magnetic resonance recording may be superimposed, such that resolution is no longer possible in the context of the post-correction. Outside of the normally specified field of view, e.g. outside of a diameter of 500 mm, the distortion is however often very pronounced due to significant B0 field inhomogeneities and gradient non-linearities. It can therefore be advantageous to combine the above described method for warp correction with sequence-based distortion reduction. Destructive superimposition effects of the non-linearities of the gradient field with the inhomogeneities of the B0 field can be utilized for the purpose of sequence-based distortion reduction, for example.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, tangible computer readable medium and tangible computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a tangible computer readable medium and is adapted to perform any one of the aforementioned methods when run on a computer device (a device including a processor). Thus, the tangible storage medium or tangible computer readable medium, is adapted to store information and is adapted to interact with a data processing facility or computer device to execute the program of any of the above mentioned embodiments and/or to perform the method of any of the above mentioned embodiments.

The tangible computer readable medium or tangible storage medium may be a built-in medium installed inside a computer device main body or a removable tangible medium arranged so that it can be separated from the computer device main body. Examples of the built-in tangible medium include, but are not limited to, rewriteable non-volatile memories, such as ROMs and flash memories, and hard disks. Examples of the removable tangible medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

### LIST OF REFERENCE SIGNS

1 Magnetic resonance facility
2 Tomograph
3 Examination table
4 Patient, examination object
5 Opening
6 Control unit
7 Evaluation device
8 Drive unit
9 Volume, field of view
10 Circumferential region
11 Arm
12 Device
13 Data medium
14 Memory
15 Processing unit
16 Interface
21-28 Step
30 Magnetic resonance recording
31 Examination object
40 Magnetic resonance recording

What is claimed is:

1. A method for correcting a distortion in a magnetic resonance recording, the magnetic resonance recording including image points of a sectional image recording of an examination object in a magnetic resonance facility and the distortion in the magnetic resonance recording indicating a mismatch between a distorted position of an image point in the magnetic resonance recording and an actual position of the image point in the examination object, the method comprising:
determining a B₀ field deviation and a gradient field deviation for at least one actual position in the magnetic resonance facility;
capturing the magnetic resonance recording of the examination object in the magnetic resonance facility; and
determining the actual position of an image point of the magnetic resonance recording as a function of the distorted position of the image point in the magnetic resonance recording, the B₀ field deviation at the actual position and the gradient field deviation at the actual position.

2. The method as claimed in claim 1, wherein the determination of the B₀ field deviation and of the gradient field deviation for the at least one actual position in the magnetic resonance facility comprises:
capturing a B₀ field strength and a gradient field strength at the at least one actual position in the magnetic resonance facility,
determining an ideal B₀ field strength and an ideal gradient field strength for the at least one actual position, determining the B₀ field deviation as a function of the captured B₀ field strength and the ideal B₀ field strength, and determining the gradient field deviation as a function of the captured gradient field strength and the ideal gradient field strength.

3. The method as claimed in claim 1, wherein the determination of the B₀ field deviation and of the gradient field deviation for the at least one actual position in the magnetic resonance facility comprises capturing a B₀ field strength and a gradient field strength at the at least one actual position in the magnetic resonance facility by way of a magnetic resonance sensor.

4. The method as claimed in claim 1, wherein moreover a corrected magnetic resonance recording is determined by virtue of an image point at an actual position in the corrected magnetic resonance recording being assigned the image point of the corresponding distorted position in the captured magnetic resonance recording.

5. The method as claimed in claim 4, further comprising:
determining an arrangement of the examination object in the magnetic resonance facility on the basis of the corrected magnetic resonance recording, and
determining an attenuation adjustment for a positron emission tomography recording as a function of the arrangement of the examination object in the magnetic resonance facility.

6. The method as claimed in claim 1, wherein the magnetic resonance facility features a tunnel-shaped opening for accommodating the examination object, wherein a margin of a field of view of the magnetic resonance facility comprises a circumferential region along an inner surface of the tunnel-shaped opening, wherein the B₀ field in the circumferential region does not satisfy a predetermined homogeneity criterion, and wherein the at least one actual position is located in the circumferential region.

7. The method as claimed in claim 6, wherein the circumferential region includes a thickness of approximately 5 cm.

8. The method as claimed in claim 1, wherein the magnetic resonance recording is captured in a transverse plane relative to the examination object.

9. The method as claimed in claim 1, wherein the actual position x, y, z of an image point of the magnetic resonance recording is determined as a function of the distorted position x₁, y₁, z₁ of the image point in the magnetic resonance recording, the B₀ field deviation dB₀ at the actual position x, y, z, the gradient field deviation dB_{gx}, dB_{gy}, dB_{gz} at the actual position x, y, z and gradient field strengths Gₓ, G_{y}, G_{z} in accordance with the equations:
$${z}_{1} = z + \frac{{dB}_{gz} ( x , y , z )}{{G}_{z}} + \{ \begin{matrix}\frac{{dB}_{0} ( x , y , z )}{{G}_{z}} & if {G}_{z} is not a phase encoding gradient \\ 0 & if {G}_{z} is a phase encoding gradient\end{matrix} \\ {x}_{1} = x + \frac{{dB}_{gx} ( x , y , z )}{{G}_{x}} + \{ \begin{matrix}\frac{{dB}_{0} ( x , y , z )}{{G}_{x}} & if {G}_{x} is not a phase encoding gradient \\ 0 & if {G}_{x} is a phase encoding gradient\end{matrix} \\ {y}_{1} = y + \frac{{dB}_{gy} ( x , y , z )}{{G}_{y}} + \{ \begin{matrix}\frac{{dB}_{0} ( x , y , z )}{{G}_{y}} & if {G}_{y} is not a phase encoding gradient \\ 0 & if {G}_{y} is a phase encoding gradient .\end{matrix}$$

10. A device for correcting a distortion in a magnetic resonance recording, wherein the magnetic resonance recording includes image points of a sectional image recording of an examination object in a magnetic resonance facility, and wherein a distortion in the magnetic resonance recording indicates a mismatch between a distorted position of an image point in the magnetic resonance recording and an actual position of the image point in the examination object, the device comprising:
an interface configured to receive a magnetic resonance recording;
a memory configured to store a B₀ field deviation and a gradient field deviation for at least one actual position in the magnetic resonance facility; and
a processing unit configured to receive the magnetic resonance recording of the examination object from the magnetic resonance facility via the interface, and to determine the actual position of an image point of the magnetic resonance recording as a function of the distorted position of the image point in the magnetic resonance recording, the B₀ field deviation at the actual position and the gradient field deviation at the actual position.

11. The device as claimed in claim 10, wherein the processing unit is configured to determine the B₀ field deviation and the gradient field deviation for at least one actual position in the magnetic resonance facility; capture the magnetic resonance recording of the examination object in the magnetic resonance facility; and determine the actual position of an image point of the magnetic resonance recording as a function of the distorted position of the image point in the magnetic resonance recording, the B₀ field deviation at the actual position and the gradient field deviation at the actual position.

12. A magnetic resonance facility, comprising:
a control unit, configured to activate a tomograph, including a magnet to generate a B₀ field in a field of view of the magnetic resonance facility, and configured to receive signals that have been picked up by the tomograph, and
an evaluation device configured to evaluate the signals and generate magnetic resonance recordings, wherein the magnetic resonance facility further comprises the device as claimed in claim 10.

13. The magnetic resonance facility as claimed in claim 12, further comprising a positron emission tomograph.

14. A computer program product, directly loadable into a memory of a programmable processing unit of a device for correcting a distortion, including program segments for executing the method as claimed in claim 1 when the program is executed in the processing unit.

15. An electronically readable data medium on which is stored electronically readable control information that is so configured as to perform the method as claimed in claim 1 when said data medium is used in a processing unit of a device for correcting a distortion.

16. The method as claimed in claim 2, wherein the determination of the B₀ field deviation and of the gradient field deviation for the at least one actual position in the magnetic resonance facility comprises capturing a B₀ field strength and a gradient field strength at the at least one actual position in the magnetic resonance facility by way of a magnetic resonance sensor.

17. A magnetic resonance facility, comprising:
a control unit, configured to activate a tomograph, including a magnet to generate a B₀ field in a field of view of the magnetic resonance facility, and configured to receive signals that have been picked up by the tomograph, and
an evaluation device configured to evaluate the signals and generate magnetic resonance recordings, wherein the magnetic resonance facility further comprises the device as claimed in claim 11.

18. The magnetic resonance facility as claimed in claim 17, further comprising a positron emission tomograph.

19. A computer readable medium including program segments for, when executed on a computer device, causing the computer device to implement the method of claim 1.
